(19) United States
(12) Patent Application Publication
(10) Pub. No.: US 2014/0001510 A1
(43) Pub. Date: Jan. 2, 2014

(54) LIGHT EMITTING ELEMENT AND METHOD OF PRODUCING THE SAME

(71) Applicants: Yu-Chao WU, Taipei City (TW); Yan LIU, Dongguan city (CN); Kuan-Chen WU, New Taipei City (TW); Ruei-Chin WANG, Zhongli City (TW); Hauw-Ming CHEN, Taichung City (TW)

(72) Inventors: Yu-Chao WU, Taipei City (TW); Yan LIU, Dongguan city (CN); Kuan-Chen WU, New Taipei City (TW); Ruei-Chin WANG, Zhongli City (TW); Hauw-Ming CHEN, Taichung City (TW)

(21) Appl. No.: 13/933,709

(22) Filed: Jul. 2, 2013

(30) Foreign Application Priority Data
Jul. 2, 2012 (CN) 201210227813.5

(51) Int. Cl. H01L 33/38

(52) U.S. Cl. CPC H01L 33/38
USPC 257/99; 438/29

(57) ABSTRACT

A light emitting element includes: a substrate; a first electrically conductive semiconductor layer located on the substrate; a light emitting layer located on a top surface of the first electrically conductive semiconductor layer; a second electrically conductive semiconductor layer located on a top surface of the light emitting layer; a positive electrode located on a top surface of the second electrically conductive semiconductor layer; and a negative electrode at least partially located on a side surface of the first electrically conductive semiconductor layer.

### FIELD

This disclosure relates to the technical field of light emitting elements, and more particularly, to a light emitting element and a method of producing the same.

### BACKGROUND

FIG. 1 is a structural diagram of a GaN (gallium nitride) light emitting diode in the prior art. As shown in FIG. 1, the light emitting diode comprises a n-type GaN layer 20, a light emitting layer 30, a p-type GaN layer 40 and an ITO (indium tin oxide) layer 90 formed in this order on a substrate 10, wherein a part of the n-type GaN layer 20 and a part of the p-type GaN layer 40 are etched to expose a part of the n-type GaN layer 20; a negative electrode 82 is formed on the exposed n-type GaN layer 20, and a positive electrode 81 is formed on the p-type GaN layer 40 and the ITO layer 90; and a protective layer 61 is formed on the positive electrode 81, the ITO layer 90, the n-type GaN layer 20 and the negative electrode 82 respectively.

Since the substrate 10 made of sapphire is not electrically conductive, the electrodes must be provided on the top surface of the light emitting diode. That is to say, the positive electrode 81 is formed on the top surface of the p-type GaN layer 40, and the negative electrode 82 is formed on the top surface of the n-type GaN layer 20. In this structure, no matter how the light emitting electrode is placed, the electric current direction thereof is vertical. However, when the negative electrode 82 is being produced, it is necessary to etch the light emitting diode from the surface of the p-type GaN layer 40 to the n-type GaN layer 20, and the etched groove must be wide enough in order to form the negative electrode 82 on the surface of the n-type GaN layer 20 through wire bonding. As a result, a part of the light emitting area originally formed by the area where the light emitting layer 30 is provided is etched, and the light emitting effect may be affected; on the other hand, since the substrate 10 made of sapphire has low thermal conductivity, it may be difficult to timely dissipate the heat generated when the LED emits light, and the performance of the LED may be deteriorated.

### SUMMARY

The technical problem to be solved by the embodiments includes at least one of the following: how to reduce the light shielding area of the light emitting element, how to improve the electric current distribution efficiency, or how to increase the light emitting area of the light emitting element.

A light emitting element is provided, which comprises: a substrate; a first electrically conductive semiconductor layer located on the substrate; a light emitting layer located on a top surface of the first electrically conductive semiconductor layer; a second electrically conductive semiconductor layer located on a top surface of the light emitting layer; a positive electrode located on a top surface of the second electrically conductive semiconductor layer; and a negative electrode at least partially located on a side surface of the first electrically conductive semiconductor layer.

A method of producing a light emitting element is provided, which comprises the steps of: forming a first electrically conductive semiconductor layer on a substrate; forming a light emitting layer on a top surface of the first electrically conductive semiconductor layer; forming a second electrically conductive semiconductor layer on a top surface of the light emitting layer; forming a first groove extending from the second electrically conductive semiconductor layer to the first electrically conductive semiconductor layer; forming a reflective layer on a top surface of the second electrically conductive semiconductor layer and on a bottom surface and a peripheral surface of the first groove; forming an electrode layer on the reflective layer; and a separation step for removing a part of the reflective layer and a part of the electrode layer so that the electrode layer is separated into a positive electrode located on the top surface of the second electrically conductive semiconductor layer and a negative electrode at least partially located on a side surface of the first electrically conductive semiconductor layer.

In the light emitting diode and the method of producing the same according to the embodiments, by forming the negative electrode on the side surface of the light emitting element, the light shielding area of the conventional light emitting element can be effectively reduced, and/or the electric current distribution efficiency can be improved; moreover, since less part of the light emitting layer needs to be etched to form the negative electrode on the side surface, the light emitting area can be increased, and/or the light emitting quality of the light emitting element can be improved; on the other hand, according to further embodiments, since the light emitting layer which generates heat can be configured closer to the printed circuit board (PCB), the thermal conductivity effect may be improved; further, since the light emitting element produced through the method provided by the embodiments can be bonded or soldered to the PCB by adopting the flip-chip technique, the wire connection cost may be reduced.

### BRIEF DESCRIPTION OF THE DRAWINGS

FIG. 1 is an illustrative structural diagram of a GaN light emitting diode in the prior art;

FIG. 2 is a flow chart of a method of producing a light emitting element according to one embodiment;

FIGS. 3(a)-3(d) illustrate cross sectional views in respective steps of the method of producing a light emitting element according to one embodiment;

FIG. 3(e) illustrates a perspective view corresponding to FIG. 3(d);

FIG. 4 illustrates a cross sectional view in a method of producing a light emitting element according to another embodiment;

FIG. 5 is an illustrative diagram showing the coupling between the light emitting element shown in FIG. 4 and a PCB;

FIGS. 6(a)-6(e) illustrate cross sectional views in respective steps of a method of producing a light emitting element according to a further embodiment;

FIGS. 7(a)-7(b) are respectively an illustrative structural diagram of a PCB to be coupled to the light emitting element shown in FIG. 6(e) and a structural diagram showing the situation after packaging;

FIG. 8 illustrates a cross sectional view of a light emitting element having an inclined negative electrode according to one embodiment;

FIG. 9 illustrates a cross sectional view of a light emitting element having an inclined negative electrode according to another embodiment;

FIGS. 10(a)-10(b) illustrate respectively a perspective view and a cross sectional view of a light emitting element having a negative electrode on three surfaces according to one embodiment;

FIG. 11 illustrates a perspective view of a light emitting element having a negative electrode on two surfaces according to one embodiment;

FIG. 12 illustrates a perspective view of a light emitting element having a negative electrode on two surfaces according to another embodiment;

FIG. 13 illustrates a perspective view of a light emitting element having a negative electrode on one surface according to one embodiment;

FIGS. 14(a)-14(c) illustrate respectively a perspective view, a cross sectional view and a top view of a light emitting element having several positive electrodes according to one embodiment;

FIG. 15 illustrates a top view of a light emitting element having several positive electrodes according to another embodiment;

FIG. 16 illustrates a structural diagram of light emitting element after packaging according to one embodiment;

FIGS. 17(a)-17(b) illustrate respectively a cross sectional view and a top view of a high-voltage LED according to one embodiment.

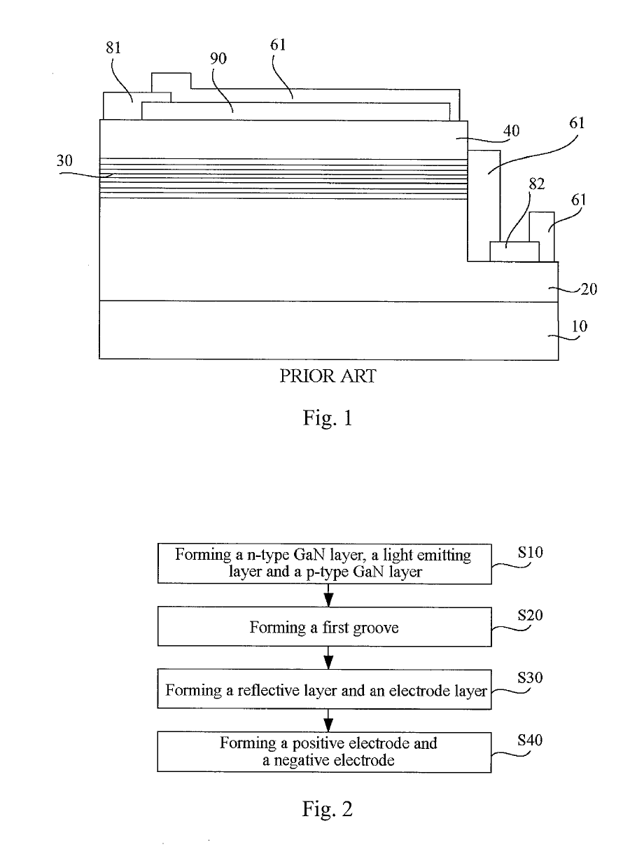

### EXPLANATION OF REFERENCE NUMERALS

10: substrate; 20: n-type GaN layer; 30: light emitting layer; 40: p-type GaN layer; 50: first groove; 60: second groove; 61: protective layer; 70: reflective layer; 80: electrode layer; 81: positive electrode; 82: negative electrode; 90: ITO layer; 91: PCB; 92: thermally conductive insulation layer; 93: slot.

### DETAILED DESCRIPTION

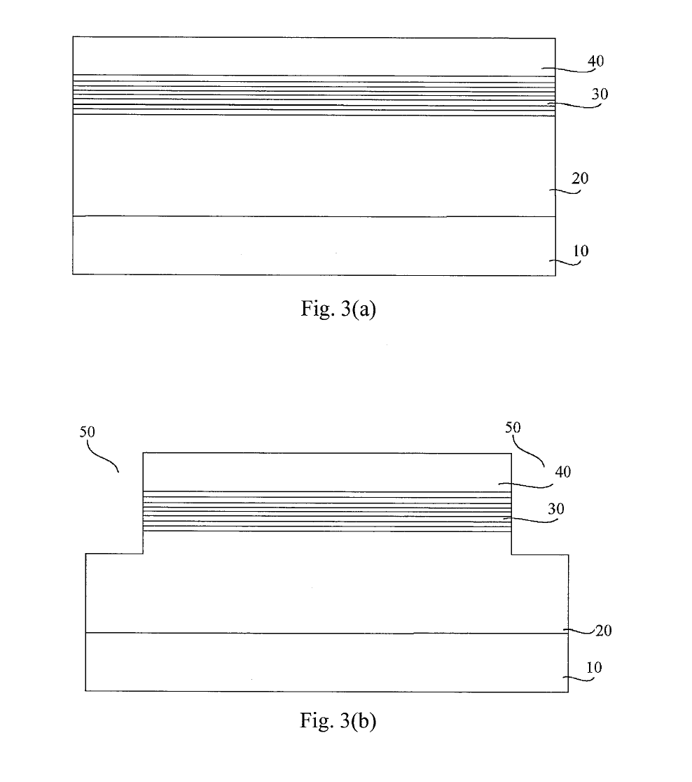

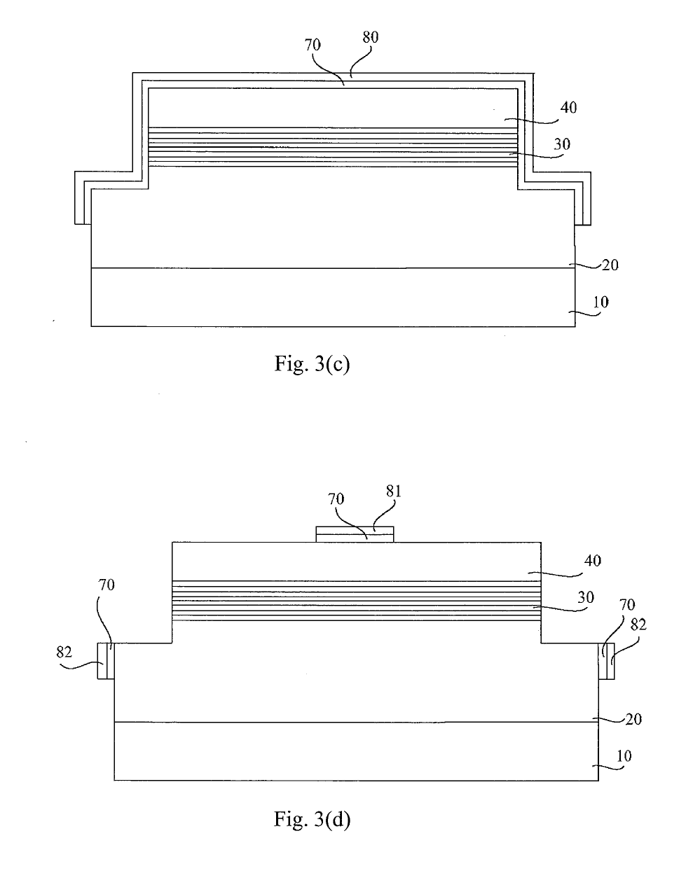

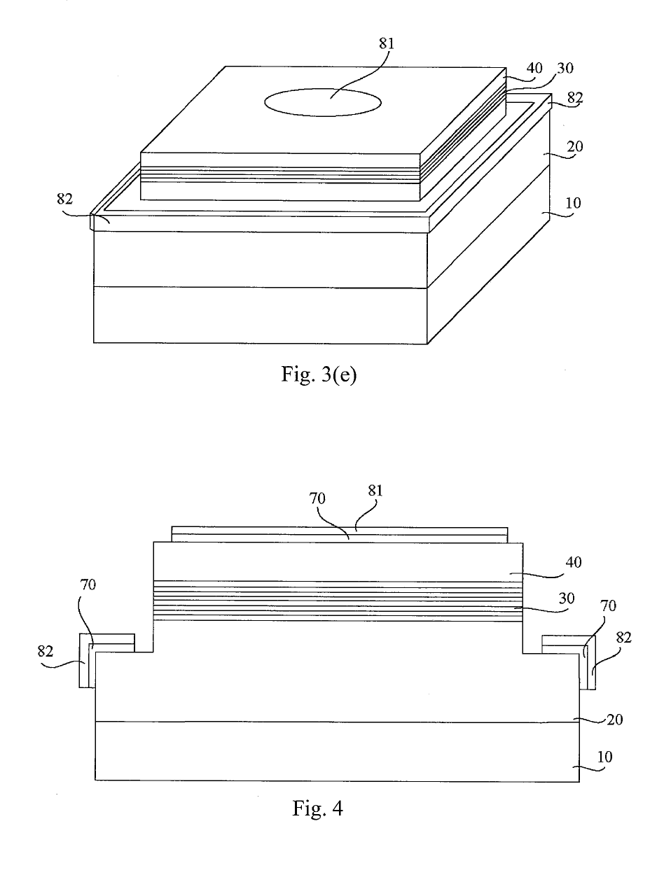

FIG. 3(d) is a structural diagram of a light emitting element according to one embodiment, the light emitting element comprising: a substrate 10; a first electrically conductive semiconductor layer 20, a light emitting layer 30 and a second electrically conductive semiconductor layer 40 formed in this order on the substrate 10; a positive electrode 81; and a negative electrode 82, where the positive electrode 81 is formed on a top surface of the second electrically conductive semiconductor layer 40, and the negative electrode 82 is at least partially formed on a side surface of the first electrically conductive semiconductor layer 20.

In a possible implementation, the first electrically conductive semiconductor layer 20 in this embodiment is made of a n-type GaN layer, and the second electrically conductive semiconductor layer 40 is made of a p-type GaN layer.

In this embodiment, the surface of the p-type GaN layer 40 that is away from the light emitting layer 30 is called a top surface, and the surface of the p-type GaN layer 40 that comes into contact with the light emitting layer 30 is called a back surface, and the remaining four surfaces of the p-type GaN layer 40 are called side surfaces. The surface of the n-type GaN layer 20 that comes into contact with the light emitting layer 30 is called a top surface, and the surface of the n-type GaN layer 20 that comes into contact with the substrate 10 is called a back surface. The surface of the light emitting layer 30 that comes into contact with the p-type GaN layer 40 is called a top surface, and the surface of the light emitting layer 30 that comes into contact with the n-type GaN layer 20 is called a back surface, and the four surfaces of the light emitting layer 30 that do not come into contact with the n-type GaN layer 20 and the p-type GaN layer 40 are called side surfaces.

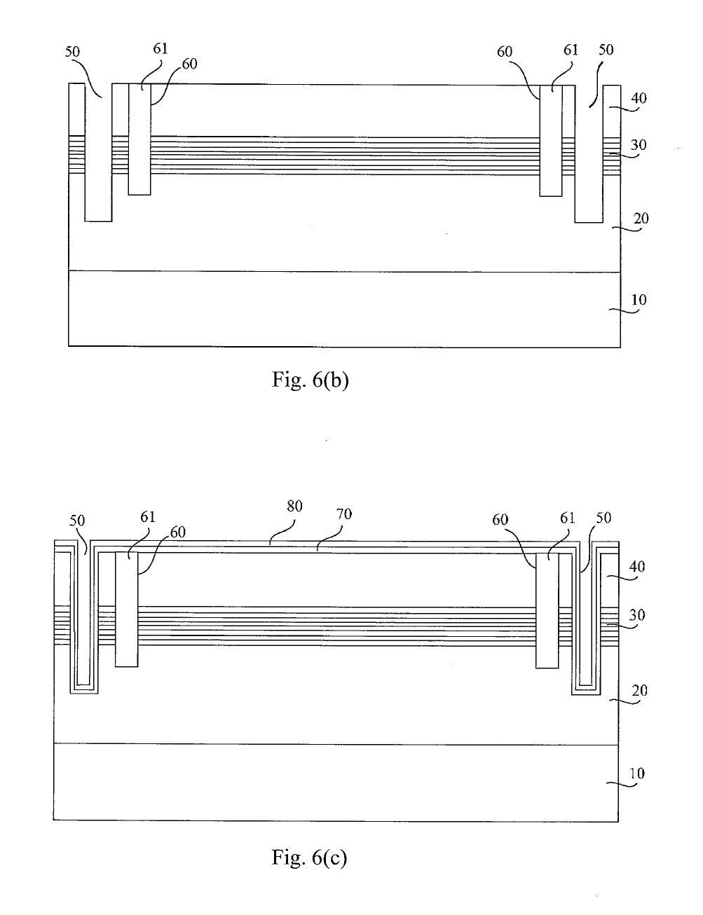

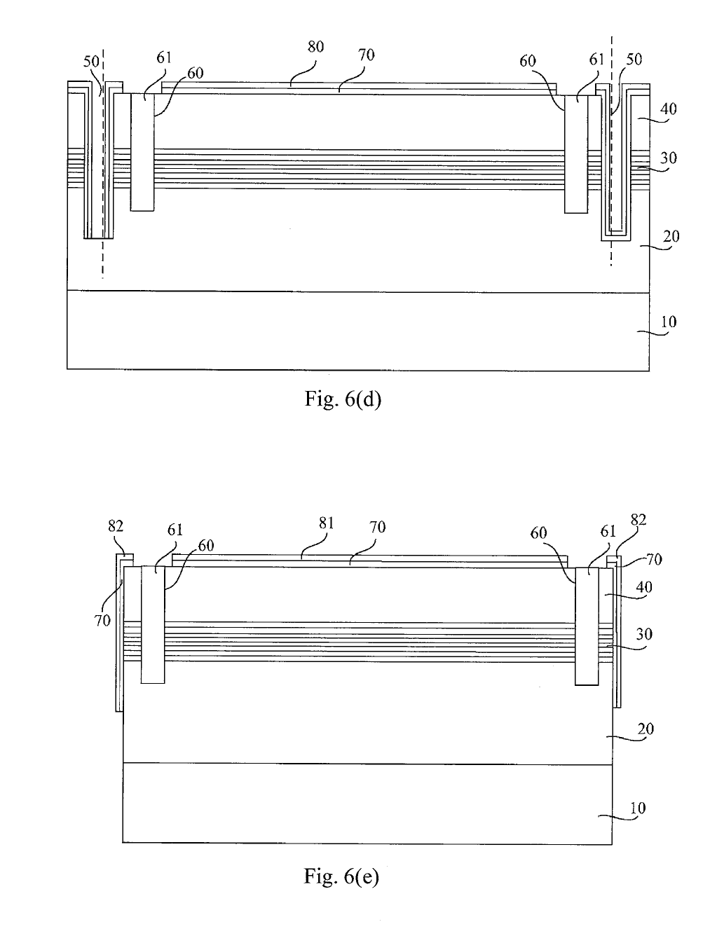

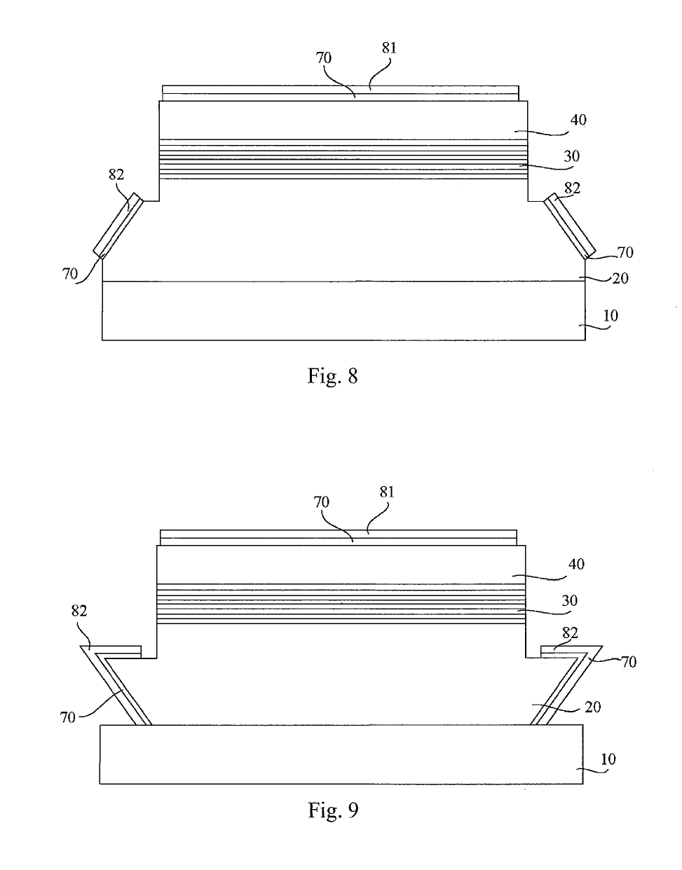

In a possible implementation of this embodiment, the negative electrode 82 is only formed on the side surface of the n-type GaN layer 20 in a direction perpendicular to the horizontal plane where the n-type GaN layer 20 is provided. In other embodiments, the negative electrode 82 may also be formed on the side surface and the surface substantially parallel to the top surface of the n-type GaN layer 20 based on actual demands (the structure is shown in FIG. 4); the negative electrode 82 may also be formed on the side surface of the n-type GaN layer 20, on the side surface of the light emitting layer 30, on the side surface of the p-type GaN layer 40, and on the top surface of the p-type GaN layer 40 (the structure is shown in FIG. 6(e)), as long as a part of the negative electrode 82 is located on the side surface of the n-type GaN layer 20. Besides, the negative electrode 82 may also be obliquely formed on the side surface of the n-type GaN layer 20 (the structure is shown in FIG. 8), under such a circumstance, the side surface of the n-type GaN layer 20 on which the negative electrode 82 is formed may also be a corresponding inclined surface; the negative electrode 82 may also be obliquely formed on the side surface and the surface substantially parallel to the top surface of the n-type GaN layer 20 (the structure is shown in FIG. 9). When the negative electrode 82 is obliquely formed, such a structure may be more advantageous for performing the subsequent packaging process.

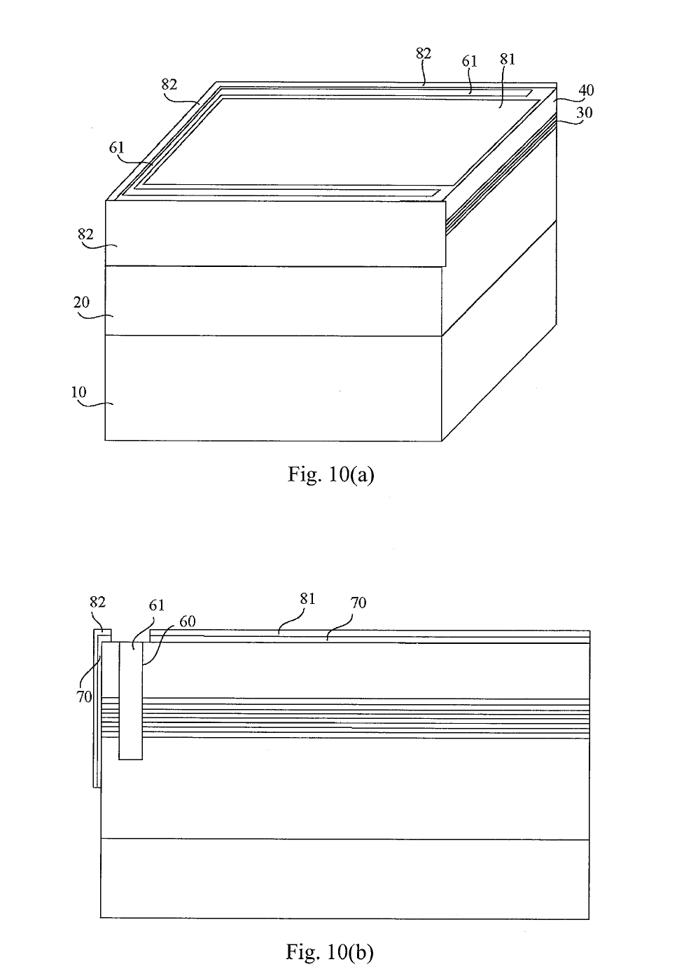

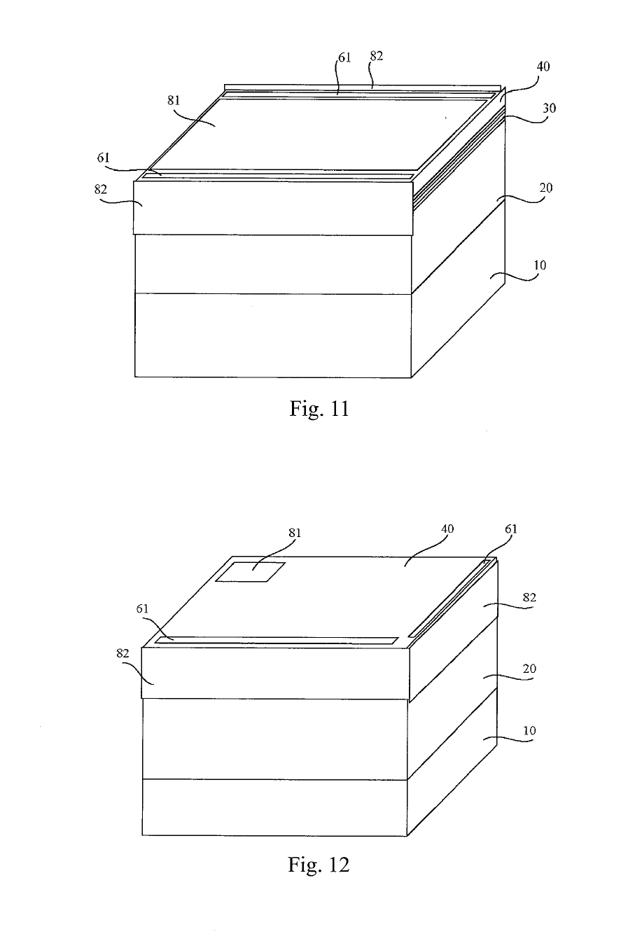

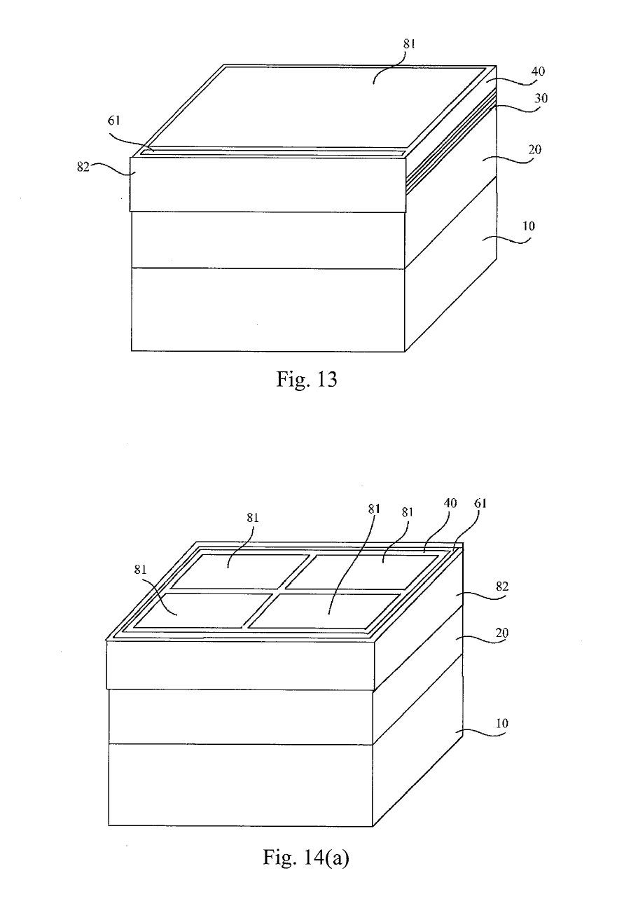

Moreover, the negative electrode 82 in this embodiment may be formed on four side surfaces of the n-type GaN layer 20 (the structure is shown in FIG. 3(e)); the negative electrode 82 may also be formed on three side surfaces of the n-type GaN layer 20 based on actual demands (the structure is shown in FIGS. 10(a)-10(b)); the negative electrode 82 may also be formed on two side surfaces of the n-type GaN layer 20, and the two side surfaces may be opposite to each other (the structure is shown in FIG. 11) or adjacent to each other (the structure is shown in FIG. 12); the negative electrode 82 may also be only formed on one side surface of the n-type GaN layer 20 (the structure is shown in FIG. 13). In the above possible implementations, the light emitting element having the negative electrode 82 formed on four side surfaces of the n-type GaN layer 20 may have the highest electric current distribution efficiency.

Further, the light emitting element according to this embodiment may also comprise a protective layer 61 formed between the positive electrode 81 and the negative electrode 82 and extending from the p-type GaN layer 40 to the n-type GaN layer 20 (the structure is shown in FIG. 6(e)).

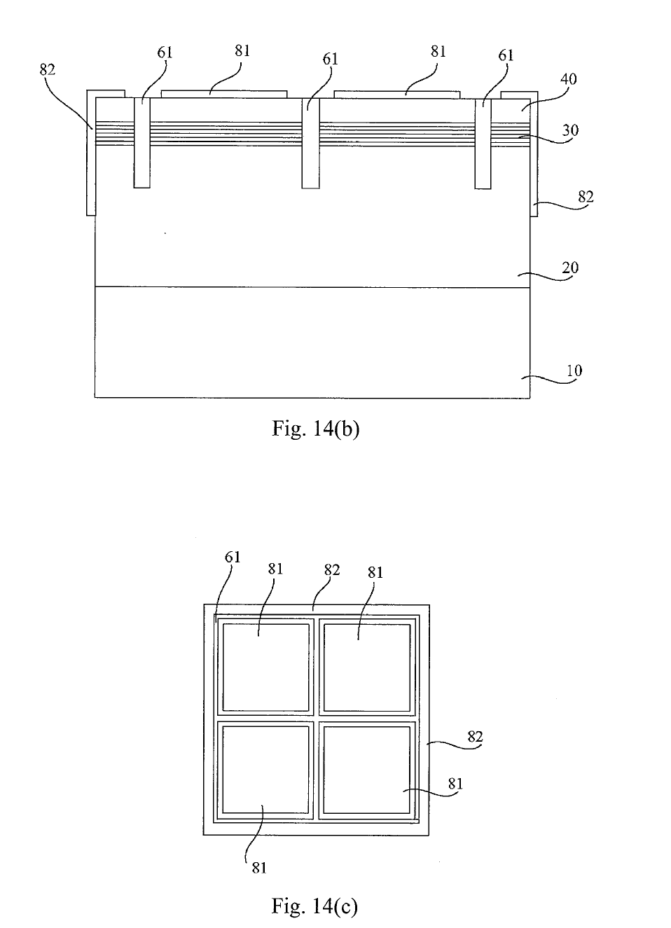

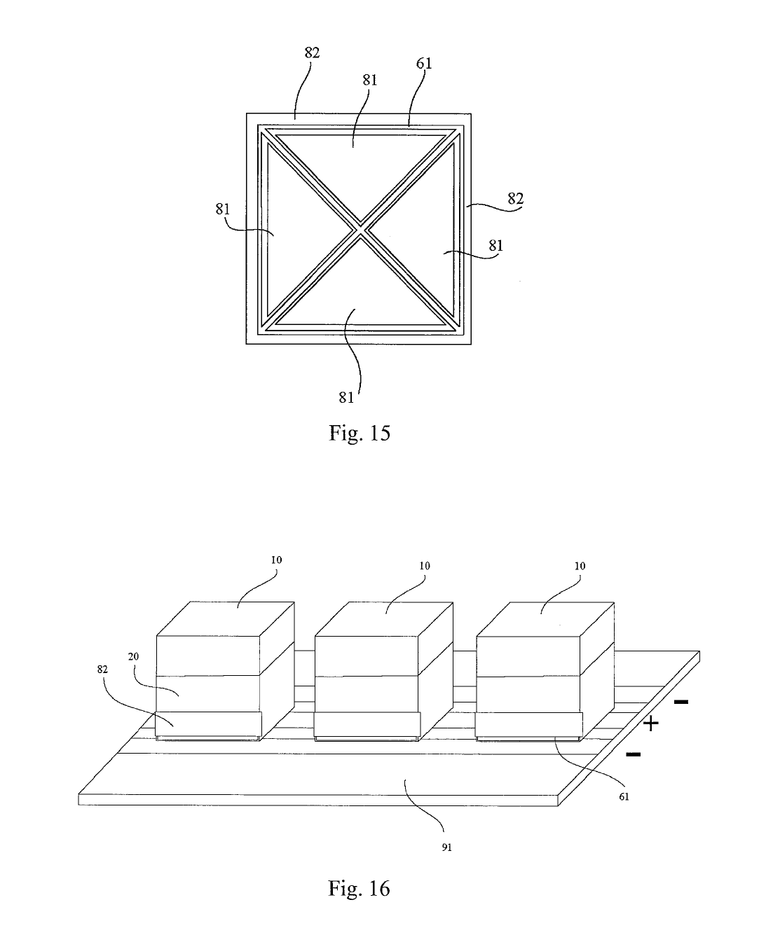

In addition, in order to improve the electric current distribution efficiency, and considering that the electric conduction only by means of the negative electrode 82 on the side surface when the light emitting element is too large might make less electric current flowing to the middle portion of the light emitting element which may reduce the light emitting efficiency of the middle portion, the protective layer 61 may be designed in a grid shape (e.g. “ [symbol] ” shape) or to have several stripes so as to divide the positive electrode 81 into several rectangles (the structure is shown in FIGS. 14(a)-14(c)) or triangles (the structure is shown in FIG. 15) or electrodes having other shapes, and several positive electrodes 81 can be coupled together. Alternatively, the shape (such as a spiral shape) and length of the negative electrode 82 may be arranged in such a manner that the negative electrode 82 is close to the positive electrode 81 at the middle portion of the light emitting element.

FIG. 2 is a flow chart of a method of producing a light emitting element according to one embodiment, and as shown in FIGS. 3(a)-3(d), the method comprising:

Step S 10: Forming the first electrically conductive semiconductor layer 20, the light emitting layer 30 and the second electrically conductive semiconductor layer 40 in this order on the substrate 10.

In this embodiment, the substrate 10 is a sapphire substrate. The material of the first electrically conductive semiconductor layer 20 may be n-type GaN or n-type AlGaInP. The material of the second electrically conductive semiconductor layer 40 may be p-type GaN or p-type AlGaInR In a possible implementation, the first electrically conductive semiconductor layer 20 and the second electrically conductive semiconductor layer 40 are made of n-type GaN and p-type GaN respectively.

Step S20: Forming at least one first groove 50 on the structure obtained from step S10 and shown in FIG. 3(a), the first groove 50 extending from the p-type GaN layer 40 to the n-type GaN layer 20.

In this step, the number, width and shape of the first groove 50 are not specifically defined. The first groove 50 may be formed on four side surfaces and have a loop shape. The first groove 50 may also be formed on one, two or three side surface(s).

Step S30: Forming the reflective layer 70 and the electrode layer 80 in this order on the structure obtained from step S20 and shown in FIG. 3(b).

Specifically, the reflective layer 70 may be formed on the top surface of the p-type GaN layer 40, and on the bottom surface and the peripheral surface of the first groove 50. The material of the reflective layer 70 may be metal or semiconductor having good electric conductivity. When the reflective layer 70 is being formed, in order to increase the contact area with the surface, the step coverage process in the prior art may be adopted. The material of the electrode layer 80 is gold or any other kind of electrically conductive metal, and the electrode layer 80 may completely cover the reflective layer 70, as shown in FIG. 3(c). This step can be realized through the plated film process.

Step S40: Removing part of the reflective layer 70 and part of the electrode layer 80 so that the electrode layer 80 is separated into the positive electrode 81 located on the top surface of the p-type GaN layer 40 and the negative electrode 82 located on the side surface of the n-type GaN layer 20.

This step can be realized through the etching or peeling process. The size of the positive electrode 81 differs as the packaging method differs. If the flip-flop technique is adopted to perform the packaging, the larger is the area of the positive electrode 81, the better (as shown in FIGS. 10(a)-10(b)). If the conventional wire bonding method is adopted, the area of the positive electrode 81 needs to be as small as possible (as shown in FIG. 3(e)), as long as the connection wire can be bonded, so as to reduce the light shielding area. Moreover, the negative electrode 82 may be entirely located on the side surface of the n-type GaN layer 20, or may be partially located on the side surface of the n-type GaN layer 20. For example, the negative electrode 82 may be located on the side surface of the n-type GaN layer 20, on the side surface of the light emitting layer 30, on the side surface of the p-type GaN layer 40, and/or on the top surface of the p-type GaN layer 40.

Further, in order to protect the light emitting layer exposed due to the etching of the groove, before the step S20 or after the step S40, the method may further comprises the following step:

Step S20′: Forming at least one second groove 60 on the structure obtained from the previous step, the second groove 60 extending from the p-type GaN layer 40 to the n-type GaN layer 20, and a protective layer 61 being formed in the second groove 60.

The material of the protective layer 61 must be insulative, have low electric conductivity and a stable structure, and cannot easily have chemical reactions with other materials. In a possible implementation, the material of the protective layer 61 is silica (SiO₂).

In a possible implementation, in order to save costs, several light emitting elements can be packaged on one PCB 91 based on actual demands (the structure is shown in FIG. 16). Such a packaging method is simpler than the conventional wire bonding method, and both a light emitting element having negative electrode on one surface and a light emitting element having negative electrode on two surfaces can be packaged in this manner.

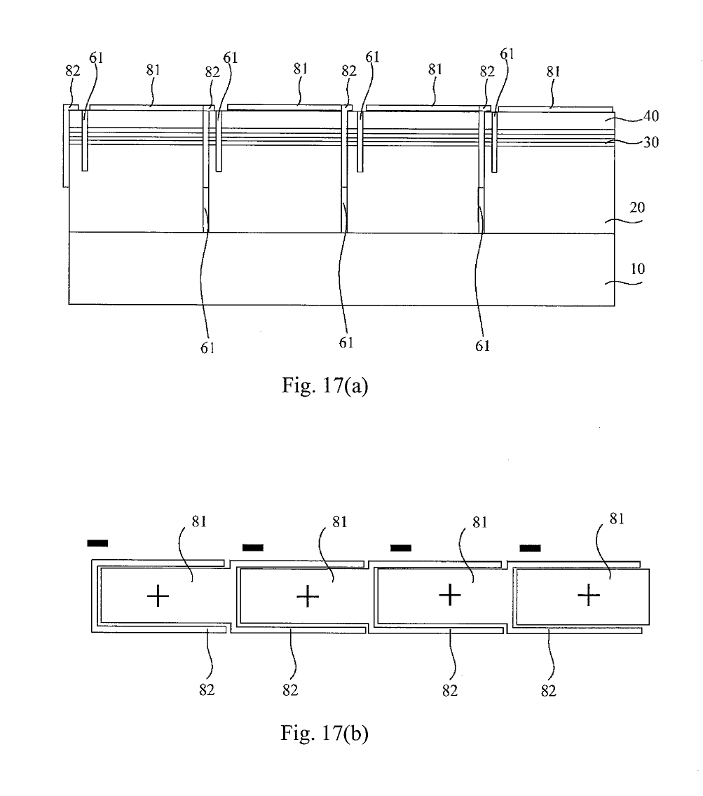

Further, several light emitting elements can be connected in series to produce a high-voltage LED (HVLED). Under such a circumstance, the first groove 50 may be etched to the substrate 10, and the negative electrodes 82 are separated from each other by the substrate 10 which is not electrically conductive. However, the electrode layer 80 is still plated on the n-type GaN layer 20. That is to say, the negative electrodes 82 are still formed on the side surfaces of the n-type GaN layer 20. The protective layer 61 is plated in the portion of the first groove 50 other than the electrode layer 80, and then the positive electrodes 81 and the negative electrodes 82 are respectively connected in series (the structure is shown in FIGS. 17(a)-17(b)).

In addition, fluorescent powder may be covered on the light emitting element in this embodiment to produce a white light LED.

Hereinafter the method of producing a light emitting element is explained in detail by the embodiments.

FIGS. 3(a)-3(d) are cross sectional views in respective steps of the method of producing a light emitting element according to the embodiment. In the light emitting element produced by this method, the positive electrode 81 is located on the top surface of the p-type GaN layer 40, and the negative electrode 82 is located on the side surface of the n-type GaN layer 20. This method comprises:

Step S101: Forming the n-type GaN layer 20, the light emitting layer 30 and the p-type GaN layer 40 in this order on the substrate 10.

In this step, the substrate 10 can be a sapphire substrate, and the structure obtained from this step is shown in FIG. 3(a).

Step S102: Forming the first groove 50 on the structure obtained from step S101.

As shown in FIG. 3(b), the first groove 50 also extends from the p-type GaN layer 40 downwardly to the n-type GaN layer 20; the first groove 50 may locate on four side surfaces of the structure obtained from step S101 and have a loop shape.

Step S103: Forming the reflective layer 70 and the electrode layer 80 in this order on the structure obtained from step S102.

As shown in FIG. 3(c), the reflective layer 70 and the electrode layer 80 in this step may locate on the top surface of the p-type GaN layer 40 and on the bottom surface and the peripheral surface of the first groove 50; the electrode layer 80 may completely cover the reflective layer 70.

Step S104: Removing a part of the reflective layer 70 and a part of the electrode 80 to separate the electrode layer 80 into the positive electrode 81 and the negative electrode 82.

As shown in FIGS. 3(d)-3(e), specifically, the reflective layer 70 and the electrode layer 80 in the first groove 50 are etched or peeled. Further, since this embodiment can adopt the wire bonding process, most of the reflective layer 70 and most of the electrode layer 80 on the top surface of the p-type GaN layer 40 are removed, and only a small part of the electrode layer 80 in the middle of the top surface of the p-type GaN layer 40 serves as the positive electrode 81.

FIG. 4 is a cross sectional view of a light emitting element in a method of producing a light emitting element according to another embodiment. In the light emitting element produced by this method, the positive electrode 81 is located on the top surface of the p-type GaN layer 40, and the negative electrode 82 is located on the side surface of the n-type GaN layer 20. This method comprises:

Steps S201-S203: The same as steps S101-S103 (see FIGS. 3(a)-3(c)).

Step S204: Removing a part of the reflective layer 70 and a part of the electrode layer 80 to separate the electrode layer 80 into the positive electrode 81 and the negative electrode 82.

As shown in FIG. 4, this step differs from step S104 in the following aspects: a part of the electrode layer at the bottom of the first groove 50 is retained, so that the electrode layer 80 located on the side surface and the surface substantially parallel to the top surface of the n-type GaN layer 20 constitutes the negative electrode 82; moreover, the light emitting element in this embodiment can be packaged by adopting the flip-flop technique, so the area of the positive electrode 81 formed on the top surface of the p-type GaN layer 40 may be as large as possible.

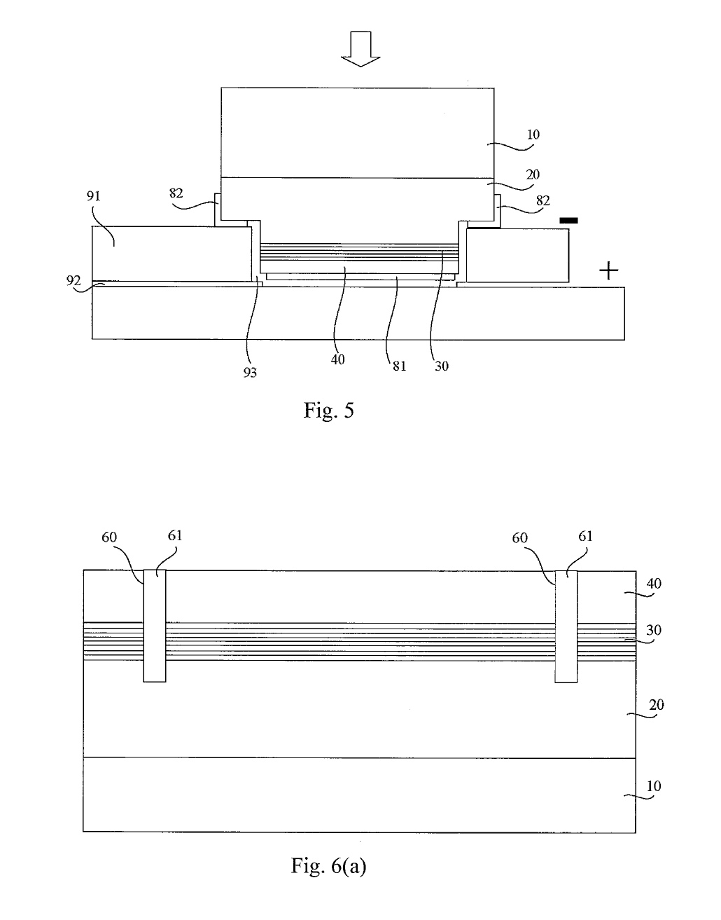

In the subsequent packaging process that adopts the flip-flop technique, as shown in FIG. 5, the light emitting element obtained from step S204 is reversed; the positive electrode 81 is soldered or bonded to the inside of the slot 93 of the PCB 91 in the arrow direction shown in FIG. 5, and the negative electrode 82 is soldered or bonded to the upper surface of the PCB 91. The PCB 91 in this embodiment can be a two-layer metal-core printed circuit board (MCPCB), and a thermally conductive insulation layer 92 is located between the two layers of metal. Under such a circumstance, the two layers of metal of the PCB 91 can be used as a positive electrode and a negative electrode respectively.

FIGS. 6(a)-(e) are cross sectional views in respective steps of a method of producing a light emitting element according to a further embodiment. In the light emitting element produced by this method, the negative electrode 82 may be formed on the top surface and the side surface of the p-type GaN layer 40, the side surface of the light emitting layer 30, and the side surface of the n-type GaN layer 20. This method comprises:

Step S301: The same as step 5101 (see FIG. 3(a)).

Step S302: Forming the second groove 60 on the structure obtained from the previous step, and forming the protective layer 61 in the second groove 60.

As shown in FIG. 6(a), in this embodiment, the second groove 60 extends from the p-type GaN layer 40 downwardly to the n-type GaN layer 20; the second groove 60 may locate on four side surfaces and have a loop shape. The material of the protective layer 61 can be SiO₂, and the protective layer 61 is used to separate the light emitting layer 30 and to prevent the light emitting layer 30 from being contaminated in the subsequent production process.

Step S303: Forming the first groove 50 on the structure obtained from step S202.

As shown in FIG. 6(b), the first groove 50 is located at the outer side of the second groove 60 and may have the same depth as that of the second groove 60 or have a larger depth than that of the second groove 60 (FIG. 6(b) shows that the first groove 50 has a larger depth than that of the second groove 60); the first groove 50 also extends from the p-type GaN layer 40 downwardly to the n-type GaN layer 20; the first groove 50 may be formed adjacent to the second groove 60 or may be arranged a distance away from the second groove 60; no matter whether the first groove 50 is adjacent to the second groove 60, the function of the formed negative electrode 82 will not be affected; in this embodiment, the first groove 50 can also have a loop shape.

Step S304: Forming the reflective layer 70 and the electrode layer 80 in this order on the structure obtained from the previous step.

Specifically, as shown in FIG. 6(c), the reflective layer 70 and the electrode layer 80 may be formed on the top surface of the p-type GaN layer 40, on the top surface of the protective layer 61, and on the bottom surface and the peripheral surface of the first groove 50.

Step S305: Removing a part of the reflective layer 70 and a part of the electrode layer 80 to separate the electrode layer 80 into the positive electrode 81 and the negative electrode 82.

Specifically, as shown in FIG. 6(d), the corresponding part of the reflective layer 70 and the electrode layer 80 on the top surface of the protective layer 61 can be etched or peeled.

Step S306: Cutting the light emitting element obtained from the previous step along the loop where the first groove 50 is provided, so as to form the positive electrode 81 located on the top surface of the p-type GaN layer 40 and the negative electrode 82 located on the top surface and the side surface of the p-type GaN layer 40, on the side surface of the light emitting layer 30, and on the side surface of the n-type GaN layer 20 (the structure is shown in FIG. 6(e)).

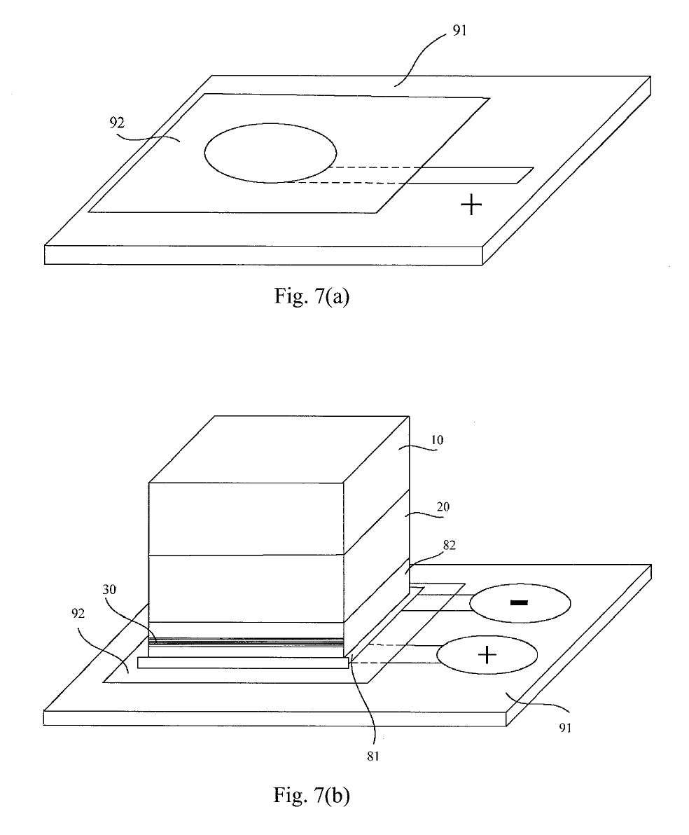

FIG. 7(a) is a structural diagram of another PCB 91. FIG. 7(b) is a structural diagram showing the situation after the light emitting element in FIG. 6(e) and the PCB 91 are packaged.

In the light emitting diode and the method of producing the same according to the embodiments, by forming the negative electrode on the side surface of the light emitting element, the light shielding area of the conventional light emitting element can be effectively reduced, and/or the electric current distribution efficiency can be improved; moreover, since less part of the light emitting layer needs to be etched in order to form the negative electrode on the side surface, the light emitting area can be increased, and/or the light emitting quality of the light emitting element can be improved; on the other hand, according to further embodiments, since the heat generated by the light emitting layer can be configured closer to the PCB, the thermal conductivity effect may be improved; further, since the light emitting element produced through the method provided by the embodiments can be bonded or soldered to the PCB by adopting the flip-chip technique, the wire connection cost may be reduced.

The above are merely embodiments of the present invention, and the protection scope of the present invention is not limited to these embodiments. Any modifications or equivalent structures and functions that can be easily thought out by a person skilled in the art within the range of the technology disclosed by the present invention should fall within the protection scope of the present invention. Thus, the protection scope of the present invention should be determined based on the protection scope of the claims.

1. A light emitting element, comprising:
a substrate;
a first electrically conductive semiconductor layer located on the substrate;
a light emitting layer located on a top surface of the first electrically conductive semiconductor layer;
a second electrically conductive semiconductor layer located on a top surface of the light emitting layer;
a positive electrode located on a top surface of the second electrically conductive semiconductor layer; and
a negative electrode at least partially located on a side surface of the first electrically conductive semiconductor layer.

2. The light emitting element according to claim 1, wherein the negative electrode is further at least partially located on the surface substantially parallel to the top surface of the first electrically conductive semiconductor layer.

3. The light emitting element according to claim 1, wherein the negative electrode is further at least partially located on a side surface of the light emitting layer, on a side surface of the second electrically conductive semiconductor layer, and on the top surface of the second electrically conductive semiconductor layer.

4. The light emitting element according to claim 1, wherein the side surface of the first electrically conductive semiconductor layer on which the negative electrode is formed is an inclined surface.

5. The light emitting element according to claim 2, wherein the side surface of the first electrically conductive semiconductor layer on which the negative electrode is formed is an inclined surface.

6. The light emitting element according to claim 1, wherein the negative electrode is at least partially located on one side surface, two side surfaces, three side surfaces or four side surfaces of the first electrically conductive semiconductor layer.

7. The light emitting element according to claim 2, wherein the negative electrode is at least partially located on one side surface, two side surfaces, three side surfaces or four side surfaces of the first electrically conductive semiconductor layer.

8. The light emitting element according to claim 3, wherein the negative electrode is at least partially located on one side surface, two side surfaces, three side surfaces or four side surfaces of the first electrically conductive semiconductor layer.

9. The light emitting element according to claim 4, wherein the negative electrode is at least partially located on one side surface, two side surfaces, three side surfaces or four side surfaces of the first electrically conductive semiconductor layer.

10. The light emitting element according to claim 5, wherein the negative electrode is at least partially located on one side surface, two side surfaces, three side surfaces or four side surfaces of the first electrically conductive semiconductor layer.

11. The light emitting element according to claim 1, further comprising a protective layer located between the positive electrode and the negative electrode and extending from the second electrically conductive semiconductor layer to the first electrically conductive semiconductor layer.

12. A method of producing a light emitting element, comprising the steps of:
forming a first electrically conductive semiconductor layer on a substrate;
forming a light emitting layer on a top surface of the first electrically conductive semiconductor layer;
forming a second electrically conductive semiconductor layer on a top surface of the light emitting layer;
forming a first groove extending from the second electrically conductive semiconductor layer to the first electrically conductive semiconductor layer;
forming a reflective layer on a top surface of the second electrically conductive semiconductor layer and on a bottom surface and a peripheral surface of the first groove;
forming an electrode layer on the reflective layer; and
a separation step for removing a part of the reflective layer and a part of the electrode layer, so that the electrode layer is separated into a positive electrode located on the top surface of the second electrically conductive semiconductor layer and a negative electrode at least partially located on a side surface of the first electrically conductive semiconductor layer.

13. The method of producing a light emitting element according to claim 12, wherein the first groove is located on one side surface, two side surfaces, three side surfaces or four side surfaces of the light emitting element.

14. The method of producing a light emitting element according to claim 12, wherein the separation step comprises:
removing a part of the reflective layer and a part of the electrode layer, so that the electrode layer is separated into a positive electrode located on the top surface of the second electrically conductive semiconductor layer and a negative electrode at least partially located on the side surface and the surface substantially parallel to the top surface of the first electrically conductive semiconductor layer.

15. The method of producing a light emitting element according to claim 12, wherein the separation step comprises:
removing a part of the reflective layer and a part of the electrode layer so that the electrode layer is separated into a positive electrode located on the top surface of the second electrically conductive semiconductor layer and a negative electrode at least partially located on the side surface of the first electrically conductive semiconductor layer, on a side surface of the light emitting layer, and on the side surface and the top surface of the second electrically conductive semiconductor layer.

16. The method of producing a light emitting element according to claim 12, further comprising:
forming a second groove extending from the second electrically conductive semiconductor layer to the first electrically conductive semiconductor layer, and forming a protective layer in the second groove.
